(19) United States
(12) Patent Application Publication
(10) Pub. No.: US 2019/0368033 A1
(43) Pub. Date: Dec. 5, 2019

(54) SELECTIVE VAPOR DEPOSITION PROCESS FOR ADDITIVE MANUFACTURING

(71) Applicant: United Technologies Corporation, Farmington, CT (US)

(72) Inventors: Thomas J. Martin, East Hampton, CT (US); Sergey Mironets, Charlotte, NC (US); Alexander Staroselsky, Avon, CT (US); Aaron T. Nardi, East Granby, CT (US)

(21) Appl. No.: 16/000,560

(22) Filed: Jun. 5, 2018

(51) Int. Cl. C23C 16/04; C23C 16/44; C23C 16/455

(52) U.S. Cl. CPC C23C 16/047; C23C 16/52; C23C 16/45578; C23C 16/4418

(57) ABSTRACT

A selective vapor deposition method is provided and includes evaporating a precursor material in a low vacuum evaporating chamber to produce a precursor vapor, evacuating the precursor vapor into a nozzle of a venturi element and accelerating the precursor vapor through a diffuser of the venturi element and toward a target build surface.

### BACKGROUND

Exemplary embodiments of the present disclosure relate generally to a selective vapor deposition process and, in one embodiment, to a selective vapor deposition process for additive manufacturing.

Discovery and development of vacuum technology, electricity, magnetism, gaseous chemistry, plasma technology, thermal evaporation, arcing and sputtering led to many advances in thin films and coatings technology. There are now many types of deposition processes, which can be qualified, based on the source material and method of deposition. For example, physical vapor deposition (PVD) begins with a condensed phase as a liquid or solid source is heated to a vapor phase and then cools to a condensed solid phase on a target build surface. Chemical vapor deposition (CVD) uses a chemical reaction to produce the vapor which decomposes onto the substrate. These processes are further characterized by the source of energy and method of deposition. For example, cathodic arc uses electric arc discharge to vaporize the source material to an ionic vapor, and electron beam physical vapor deposition (EB-PVD) uses an energetic electron beam to ablate the source material.

Each technology and its derivatives has distinct advantages and limitations based on criteria such as cost, film thickness, deposition rate, source material availability, porosity, and compositional control. There are some common constraints, however, that limit the implementation of these deposition technologies. Many depositions processes allow only line-of-sight transfer and others produce unavoidable deposition of source material on all surfaces interior to the vacuum chamber, including the holding fixtures.

### BRIEF DESCRIPTION

According to an aspect of the disclosure, a selective vapor deposition method is provided and includes evaporating a precursor material in a low vacuum evaporating chamber to produce a precursor vapor, evacuating the precursor vapor into a nozzle of a venturi element and accelerating the precursor vapor through a diffuser of the venturi element and toward a target build surface.

In accordance with additional or alternative embodiments, the evaporating of the precursor vapor includes cathodic arc evaporation.

In accordance with additional or alternative embodiments, the method further includes coupling the target build surface to a multi-axis robotic arm.

In accordance with additional or alternative embodiments, the precursor material is evaporated, vaporized, sputtered or ablated in at least one of a crucible, a boat or an ingot inside the low vacuum evaporating chamber using at least one of an electrical resistance heater, an electron beam, a cathodic arc, an ion beam and a laser beam.

In accordance with additional or alternative embodiments, the evacuating of the precursor vapor into the nozzle includes flowing an inert gas through the nozzle to entrain the precursor vapor.

In accordance with additional or alternative embodiments, the method further includes capturing and recycling unused precursor vapor.

In accordance with additional or alternative embodiments, the accelerating of the precursor vapor through the diffuser includes electro-magnetically repelling the precursor vapor.

In accordance with additional or alternative embodiments, the electro-magnetically repelling the precursor vapor includes charging the precursor vapor with a predefined charge in at least one of the low vacuum evaporization chamber, the nozzle and the diffuser and charging an interior surface of at least a portion of the diffuser with the predefined charge.

In accordance with additional or alternative embodiments, the method further includes electro-magnetic attraction of the precursor vapor toward the target build surface.

In accordance with additional or alternative embodiments, the method further includes controlling electro-magnetic repulsion of the precursor vapor along at least the portion of the diffuser.

According to another aspect of the disclosure, a selective vapor deposition apparatus includes a support frame on a portion of which a target build surface is disposable, a low vacuum evaporating chamber defining an outlet in which a precursor material is evaporated to produce a precursor vapor, which is depositable onto the target build surface and a venturi element comprising a nozzle and a diffuser and disposable with an inlet of the nozzle adjacent to the outlet and the diffuser aimed toward the target build surface, the venturi element being configured to evacuate the precursor vapor through the nozzle from the low vacuum evaporating chamber and to accelerate the precursor vapor through the diffuser toward the target build surface.

In accordance with additional or alternative embodiments, the target build surface support frame includes a multi-axis robotic arm.

In accordance with additional or alternative embodiments, the low vacuum evaporating chamber includes at least one of a crucible, a boat and an ingot, and the precursor material is evaporated, vaporized, sputtered or ablated by at least one of an electrical resistance heater, an electron beam, a cathodic arc, an ion beam and a laser beam.

In accordance with additional or alternative embodiments, a capture and recycle system captures and recycles unused precursor vapor.

In accordance with additional or alternative embodiments, wherein at least the diffuser electro-magnetically repels the precursor vapor.

In accordance with additional or alternative embodiments, the precursor vapor and at least an interior surface of a portion of the diffuser have a same charge.

In accordance with additional or alternative embodiments, electro-magnetic attraction is directed toward the target build surface.

In accordance with additional or alternative embodiments, the electro-magnetic repulsion is controllable along a portion of the diffuser.

According to yet another aspect of the disclosure, a venturi element is provided and includes a nozzle in which a precursor vapor is entrained into a flow of an inert gas and a diffuser through which the precursor vapor, which is provided for deposition onto a target build surface, and the inert gas each flow toward the target build surface, at least a portion of an interior surface of the diffuser being operable to electro-magnetically repel the precursor vapor to accelerate flows thereof through the diffuser and toward the target build surface.

In accordance with additional or alternative embodiments, the precursor vapor and the at least the portion of the interior surface of the diffuser have a same charge.

These and other advantages and features will become more apparent from the following description taken in conjunction with the drawings.

### BRIEF DESCRIPTION OF THE DRAWINGS

The following descriptions should not be considered limiting in any way. With reference to the accompanying drawings, like elements are numbered alike:

FIG. 1 is a schematic diagram of a selective vapor deposition apparatus in accordance with embodiments;

FIG. 2 is a schematic diagram of a capture and recycle system of the selective vapor deposition apparatus of FIG. 1 in accordance with embodiments;

FIG. 3 is a schematic side view of a segmented venturi element in accordance with embodiments;

FIG. 4 is a schematic diagram illustrating components of a control element of the selective vapor deposition apparatus of FIGS. 1-3; and

FIG. 5 is a flow diagram illustrating a selective vapor deposition method in accordance with embodiments.

These and other advantages and features will become more apparent from the following description taken in conjunction with the drawings.

### DETAILED DESCRIPTION

A detailed description of one or more embodiments of the disclosed apparatus and method are presented herein by way of exemplification and not limitation with reference to the Figures.

As will be described below, a method is provided for executing targeted deposition of gaseous precursor materials on specific areas of a build surface. The proposed deposition process is a form of evaporation deposition, where the precursor material is evaporated by a heating element or vaporized by an energy source into a low vacuum evaporating chamber and is then evacuated out of the chamber into a venturi nozzle of a flowing inert gas, such as argon, drawn by venturi effect. The nozzle accelerates the precursor rich gas to selectively deposit the vapor material onto the target build surface. The entire system can be under protective atmosphere in a low pressure containment enclosure. The substrate is attached to a multi-axis robotic arm, within the enclosure, and can be controlled by a computer. Clogging of the nozzle by deposition of precursor material can be avoided by electro-magnetic repulsion. Deposition on the target build surface can be increased, enhanced and controlled by electro-magnetic attraction.

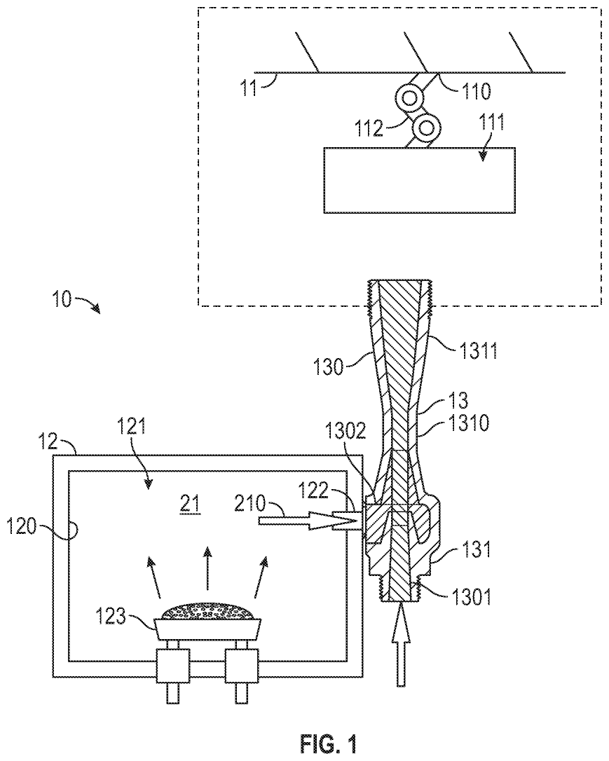

With reference to FIG. 1, a selective vapor deposition apparatus 10 is provided and includes a target build surface support frame 11, a low vacuum evaporization chamber 12 and a venturi element 13. The target build surface support frame 11 has a portion 110 thereof on which a target build surface 111 is disposable. The target build surface support frame 11 may also include a multi-axis robotic arm 112 that is controllable and allow the target build surface support frame 11 to maneuver the target build surface 111 in multiple axes and with multiple degrees of freedom. The heating chamber 12 is a body 120 that is formed to define an interior 121 and an outlet 122 through which the interior 121 is communicative with an exterior of the low vacuum evaporating chamber 12. The low vacuum evaporating chamber 12 may include at least one of a crucible, a boat and an ingot 123 in which a precursor material 20 may be provided and in which the precursor material 20 may be evaporated, vaporized, sputtered or ablated by at least one of electrical resistance heater, electron beam, cathodic arc, ion beam sputtering, and laser beam to produce a precursor vapor 21 (illustrated by the arrow 210 of FIG. 1 which is drawn to indicate that the precursor vapor 21 is exiting the heating chamber).

In accordance with embodiments, cathodic arc evaporation in particular involves striking a cathode substrate that includes source material with a high current, low voltage arc in order to produce the precursor vapor by sputtering. The cathodic spot can be controlled by the application of an electromagnetic field which moves the arc over the cathodic substrate. This cathodic process produces a precursor vapor of neutral, dissociated and ionized particles and allows for initially executing a sputtering process at the target build surface 111.

The precursor material 20 may be selected from various materials. The various materials include, but are not limited to, both metals, ceramics, intermetallics, and any of those which can be deposited as the precursor vapor 21 onto the target build surface 111.

The venturi element 13 includes a nozzle 130 and a diffuser 131. The nozzle 130 includes a first inlet 1301 and a second inlet 1302. The first inlet 1301 has a converging flow area and may be receptive of a flow of an inert gas, such as argon. The second inlet 1302 also has a converging flow area that intersects with a downstream portion of the first inlet 1301. Thus, the flow of the inert gas effectively entrains a flow of fluidic materials, such as the precursor vapor 21 into and through the second inlet 1302 so that it mixes with the flow of the inert gas leaving the first inlet 1301. The diffuser 131 includes a narrow section 1310, which is downstream from the first inlet 1301 and the second inlet 1302, and a diverging section 1311, which is downstream from the narrow section 1310. Where the precursor vapor 21 is entrained into the flow of an inert gas in the nozzle 130 (again with the flow of the precursor vapor 21 leaving the heating chamber 12 as illustrated by the arrow 210 in FIG. 1), the precursor vapor 21 and the inert gas flow through the narrow section 1310 and the diverging section 1311 of the diffuser 131.

As shown in FIG. 1, the venturi element 13 is disposable such that the second inlet 1302 fluidly communicates with the outlet 122 and such that the diverging section 1311 of the diffuser 131 is aimed toward the target build surface 111. Thus, the precursor vapor 21 is entrained into the flow of the inert gas within the nozzle 130 and then flows with the inert gas through the diffuser 131 toward the target build surface 111. That is, the venturi element 131 as a whole is configured to evacuate the precursor vapor 21 from the interior 121 of the low vacuum evaporating chamber 12. The precursor vapor 21 subsequently flows through the nozzle 130 from the heating chamber 12 and is then accelerated through the diffuser 131 toward the target build surface 111.

While the target build surface support frame 11 may include the multi-axis robotic arm 112 as described above, it is to be understood that the venturi element 13 may also be provided with a multi-axis robotic arm. Thus, one or both of the target build surface support frame 11 and the venturi element 13 can be maneuvered relative to the other in multiple axes and with multiple degrees of freedom. During a depositional process, such relative movement can allow for the deposition of the precursor vapor 21 in relatively complex patterns.

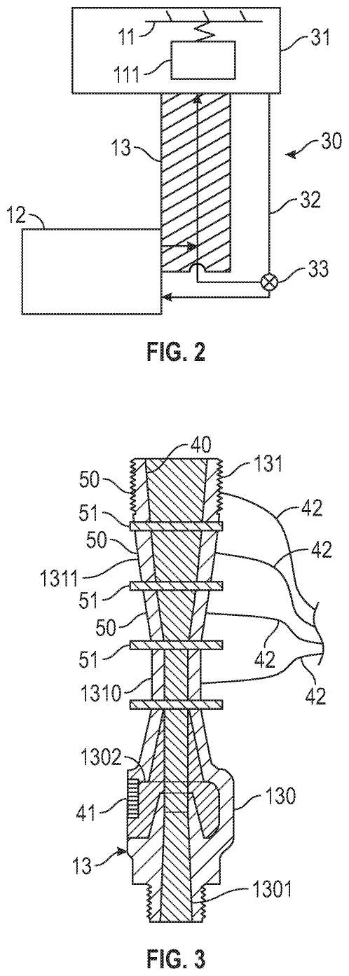

With reference to FIG. 2, the selective vapor deposition apparatus 10 may further include a capture and recycle system 30 for capturing and recycling unused precursor vapor 21 and inert gas. The capture and recycle system 30 may include a closed body 31, which surrounds the target build surface support frame 11 and the target build surface 111 and which can be purged of unused precursor vapor 21 and inert gas, and return piping 32 that returns the unused precursor vapor 21 and the inert gas to the heating chamber 12 and the first inlet 1301 (see FIG. 1), respectively. The return piping 32 may include a valve element 33 that is configured to separate the unused precursor vapor 21 from the inert gas.

With reference to FIGS. 1 and 3 and, in accordance with further embodiments, at least a portion of an interior surface 40 of the diffuser 131 may be operable to electro-magnetically repel the precursor vapor 21. Such electro-magnetic repulsion may be executed to prevent the precursor vapor 21 from depositing, condensing onto or otherwise fouling the interior surface 40 and/or to accelerate the flows of the precursor vapor 21 through the diffuser 131 and toward the target build surface 111.

In accordance with embodiments, the electro-magnetic repulsion may be executed by the provision of a first electrode 41 within the low vacuum evaporating chamber 12 or the nozzle 130 and a second electrode 42 in electrical communication with the diffuser 131. In such cases, energization of the first and second electrodes 41, 42 ionizes the precursor vapor 21 and applies a same charge to the interior surface 40 of the diffuser 131. Moreover, to an extent the entire interior surface 40 of the diffuser 131 can be charged, the electro-magnetic repulsion can prevent the deposting of the precursor vapor 21 on the interior surface 40 in the narrow section 1310 and can accelerate the precursor vapor 21 along the length of the diverging section 1311 toward the target build surface 111.

In accordance with further embodiments, to an extent that the precursor vapor 21 is charged, the target build surface 111 can be oppositely charged. Such opposite charging will generate magnetic attraction between the precursor vapor 21 and the target build surface 111 and thus encourage deposition or, in some cases, increase a speed, power and/or efficiency of such deposition.

With reference to FIG. 3 and, in accordance with further embodiments, at least the diverging section 1311 of the diffuser 131 may be formed of axial segments 50 that are electrically isolated from one another by dielectric material 51. These axial segments 50 may be respectively coupled to corresponding second electrodes 42 that are sequentially energizable to generate an electro-magnetic repulsion pattern along the length of the diverging section 1311. This electro-magnetic repulsion pattern can be generated such that the acceleration of the precursor vapor 21 toward the target build surface 111 is controllable and timed.

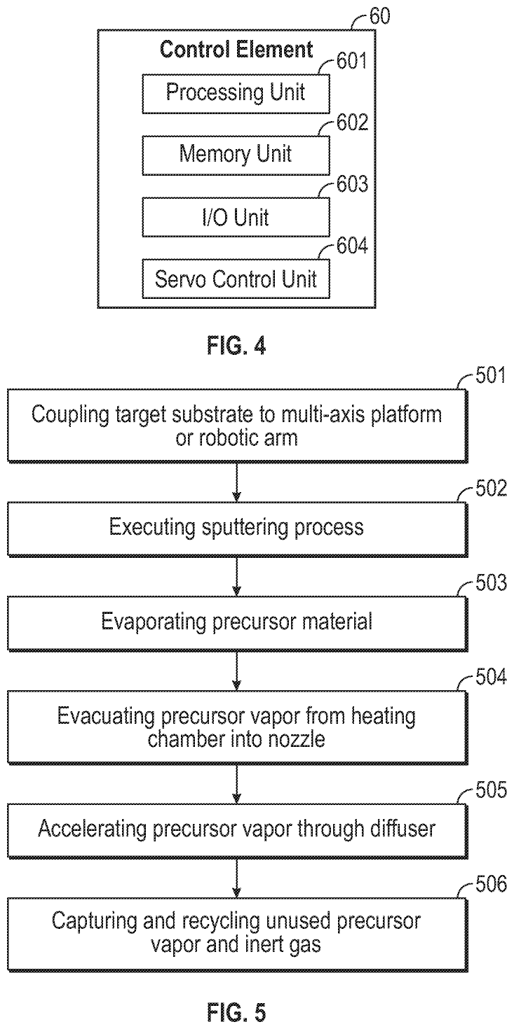

With reference to FIG. 4, the selective vapor deposition apparatus 10 may include a control element 60 that is operable to control the relative maneuvering of the venturi element 13 and the target build surface 111, operations of the low vacuum evaporating chamber 12 and the inert gas flow and the generation of the electro-magnetic repulsion. The control element 60 thus includes a processing unit 601, a memory unit 602 having executable instructions stored thereon which are readable and executable by the processing unit 601, input/output (I/O) unit 603 and a servo control unit 604. When the executable instructions are read and executed by the processing unit 601, the executable instructions cause the processing unit 601 to retrieve deposition instructions (i.e., in an additive manufacturing instance, the deposition instructions may include a part or component design as well as compositional instructions) as well as data and current condition information via the I/O unit 603, to calculate or otherwise generate operational commands for the various components of the target build surface support frame 11, the heating chamber 12, the venturi element 13, the capture and recycle system 30 and the first and second electrodes 41, 42 and to instruct the servo control unit 604 to execute the commands itself or to control the various components to execute.

With reference to FIG. 5, a selective vapor deposition method is provided for use with the selective vapor deposition apparatus 10 described above. As shown in FIG. 5, the method includes coupling the target build surface 111 to the multi-axis robotic arm 112 of the target build surface support frame 11 (501) and initially executing a sputtering process or another suitable process at the target build surface 111 to clean or prepare various surfaces thereof (502). The method further includes evaporating, vaporizing, sputtering or ablating the precursor material 20 in at least one of the crucible, a boat and ingot 123 inside the heating chamber 12 using at least one of electrical resistance heater, electron beam, cathodic arc, ion beam and laser beam to produce the precursor vapor 21 (503). At this point, the method includes evacuating the precursor vapor 21 into the nozzle 130 of the venturi element 13 by flowing the inert gas through the nozzle 130 to entrain the precursor vapor 21 (504). The precursor vapor 12 is then accelerated through the diffuser 131 of the venturi element 13 and toward the target build surface 111 (505). The accelerating of the precursor vapor 21 can be achieved by the entraining of the precursor vapor 21 into the flow of the inert gas and/or by the electro-magnetic repulsion. As an additional feature, the method may also include capturing and recycling unused precursor vapor 21 and inert gas for re-use (506).

Benefits of the features described herein are the provision of targeted deposition as opposed to existing vapor deposition methods, which cannot selectively control deposition. The selective vapor deposition apparatus 10 described above can be utilized for depositing thin and thick films on external surfaces of the target build surface 111 and most importantly on internal and out of sight surfaces of additively manufactured parts. The deposited layers will smooth such exterior and internal surfaces and will thus result in improved fatigue performance. The selective vapor deposition apparatus 10 and the method described above can be used in conjunction with cold spray deposition in which the precursor vapor 21 will be introduced to a cold spray carrier gas containing precursor powder. The precursor vapor 21 and cold spray powder can be selected to match a chemical composition of the target build surface 111, which can result in increased ductility and improved quality of the build. In addition, the selective vapor deposition apparatus 10 and the method described above can be controlled for in-situ micro-alloying of the target build surface 111 to selectively control and improve its mechanical properties.

Benefits of the features described herein are targeted delivery of a precursor material to specific areas at increased rate, controlled deposition and surface quality for additively manufactured parts, avoidance of deposition on internal and out of sight surfaces, elimination or minimization of a need for masking, modification and improvement to cold spray deposited layer, an allowance for in-situ micro alloying of powder particles and lower costs of deposition processes.

The term “about” is intended to include the degree of error associated with measurement of the particular quantity based upon the equipment available at the time of filing the application.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

What is claimed is:

1. A selective vapor deposition method, comprising:
evaporating a precursor material in a low vacuum evaporating chamber to produce a precursor vapor;
evacuating the precursor vapor into a nozzle of a venturi element; and
accelerating the precursor vapor through a diffuser of the venturi element and toward a target build surface.

2. The selective vapor deposition method according to claim 1, wherein the evaporating of the precursor material comprises cathodic arc evaporation.

3. The selective vapor deposition method according to claim 1, further comprising coupling the target build surface to a multi-axis robotic arm.

4. The selective vapor deposition method according to claim 1, wherein the precursor material is evaporated, vaporized, sputtered or ablated in at least one of a crucible, a boat or an ingot inside the low vacuum evaporating chamber using at least one of an electrical resistance heater, an electron beam, a cathodic arc, an ion beam and a laser beam.

5. The selective vapor deposition method according to claim 1, wherein the evacuating of the precursor vapor into the nozzle comprises flowing an inert gas through the nozzle to entrain the precursor vapor.

6. The selective vapor deposition method according to claim 1, further comprising capturing and recycling unused precursor vapor.

7. The selective vapor deposition method according to claim 1, wherein the accelerating of the precursor vapor through the diffuser comprises electro-magnetically repelling the precursor vapor.

8. The selective vapor deposition method according to claim 7, wherein the electro-magnetically repelling the precursor vapor comprises:
charging the precursor vapor with a predefined charge in at least one of the low vacuum evaporization chamber, the nozzle and the diffuser; and
charging an interior surface of at least a portion of the diffuser with the predefined charge.

9. The selective vapor deposition method according to claim 7, further comprising directing electro-magnetic attraction of the precursor vapor toward the target build surface.

10. The selective vapor deposition method according to claim 7, further comprising controlling electro-magnetic repulsion of the precursor vapor along at least the portion of the diffuser.

11. A selective vapor deposition apparatus, comprising:
a support frame on a portion of which a target build surface is disposable;
a low vacuum evaporating chamber defining an outlet in which a precursor material is evaporated to produce a precursor vapor, which is depositable onto the target build surface; and
a venturi element comprising a nozzle and a diffuser and disposable with an inlet of the nozzle adjacent to the outlet and the diffuser aimed toward the target build surface,
the venturi element being configured to evacuate the precursor vapor through the nozzle from the low vacuum evaporating chamber and to accelerate the precursor vapor through the diffuser toward the target build surface.

12. The selective vapor deposition apparatus according to claim 11, wherein the target build surface support frame comprises at least one a multi-axis robotic arm.

13. The selective vapor deposition apparatus according to claim 11, wherein:
the low vacuum evaporating chamber comprises at least one of a crucible, a boat and an ingot, and
the precursor material is evaporated, vaporized, sputtered or ablated by at least one of an electrical resistance heater, an electron beam, a cathodic arc, an ion beam and a laser beam.

14. The selective vapor deposition apparatus according to claim 11, further comprising a capture and recycle system for capturing and recycling unused precursor vapor.

15. The selective vapor deposition apparatus according to claim 11, wherein at least the diffuser electro-magnetically repels the precursor vapor.

16. The selective vapor deposition apparatus according to claim 15, wherein the precursor vapor and at least an interior surface of a portion of the diffuser have a same charge.

17. The selective vapor deposition apparatus according to claim 15, wherein electro-magnetic attraction is directed toward the target build surface.

18. The selective vapor deposition apparatus according to claim 15, wherein the electro-magnetic repulsion is controllable along a portion of the diffuser.

19. A venturi element, comprising:
a nozzle in which a precursor vapor is entrained into a flow of an inert gas; and
a diffuser through which the precursor vapor, which is provided for deposition onto a target build surface, and the inert gas each flow toward the target build surface,
at least a portion of an interior surface of the diffuser being operable to electro-magnetically repel the precursor vapor to accelerate flows thereof through the diffuser and toward the target build surface.

20. The venturi element according to claim 19, wherein the precursor vapor and the at least the portion of the interior surface of the diffuser have a same charge.
